(19) United States
(12) Patent Application Publication
(10) Pub. No.: US 2025/0015214 A1
(43) Pub. Date: Jan. 9, 2025

(54) METHOD FOR PRODUCING A PHOTOVOLTAIC MODULE WITH EDGE PROTECTION AND A PHOTOVOLTAIC MODULE WITH EDGE PROTECTION

(71) Applicants: China Triumph International Engineering Co., Ltd., Shanghai (CN); CTF Solar GmbH, Dresden (DE)

(72) Inventors: Shou PENG, Shanghai (CN); Liyun MA, Shanghai (CN); Alexander KATZUNG, Dresden (DE); Xinjian YIN, Shanghai (CN); Ganhua FU, Shanghai (CN)

(73) Assignees: China Triumph International Engineering Co., Ltd., Shanghai (CN); CTF Solar GmbH, Dresden (DE)

(21) Appl. No.: 18/711,887

(22) PCT Filed: Nov. 23, 2021
(86) PCT No.: PCT/CN2021/132310

§ 371 Date: May 21, 2024

(51) Int. Cl. H01L 31/048

(52) U.S. Cl. CPC H01L 31/0488

(57) ABSTRACT

A method for manufacturing a photovoltaic module with edge protection comprising: a) providing a transparent module substrate comprising a thin film solar module on a first surface of the transparent module substrate, b) applying at least two side busbars to the thin film solar module, c) placing a first encapsulation foil onto the thin film solar module, d) placing a transparent back substrate onto the first encapsulation foil, e) placing a second encapsulation foil onto a second surface of the transparent module substrate, f) placing a transparent front substrate onto the second encapsulation foil, g) laminating a substrate stack, h) placing a pressure mould over the edge of the substrate stack, i) injecting an edge protection mass into the pressure mould, and j) moving the pressure mould along the edges of the substrate stack to form a circumferential edge protection, as well as a photovoltaic module comprising an edge protection.

### TECHNICAL FIELD

The invention concerns a method for producing a photovoltaic module with edge protection and a photovoltaic module with edge protection.

### BACKGROUND TECHNOLOGY

Photovoltaic modules with edge protection are known, especially frameless photovoltaic modules.

DE 10 2008 013 523 B4 shows a solar module with a front and a back encapsulation glass, a lateral circumferential sealing element made of butyl rubber and concentrator solar cell elements arranged between the front and back encapsulation glass. The sealing element encloses the front and back glass in a u-shape or can be arranged between the front and the back glass together with an adhesive layer to fix the front and the back glass together. The sealing element, however, requires additional effort to be kept in place—either by large adhesive volume or by a clamping element of complex shape. Such a multi-component sealing element results in a complex manufacturing procedure.

WO 2011/041806 A1 discloses a method for producing an element, like a solar module, with a first and second glass substrate. Between the first and the second glass substrate at least one solar cell or one solar collector may be included, wherein the solar cell may be a wafer or a thin film foil. A string shaped diffusion tight material like butyl rubber is applied along the circumference of the first glass substrate before the first and second glass substrate are laminated together in a vacuum chamber. Such applied rubber material provides no protection of the glass edges against mechanical impact.

JPH 1168136 A discloses a solar module, consisting of a transparent protective plate, a photoelectric conversion layer and a back cover material, for instance a metal foil coated with PET or PVF on one or both sides, with a sealing frame member. The sealing member is formed by using a two-part moulding die out of a two-component urethane resin. The sealing member encompasses the solar module to a certain extent on the upper and lower surface of the solar module and therefore limiting active area of the solar module.

U.S. Pat. No. 2,011,303 287 A1 discloses an edge sealing method of a solar cell module. The solar cell module comprises an upper glass and a lower glass, wherein the solar cells are directly formed on one of the glasses and encapsulated with EVA between the upper and lower glass. The gap between the upper and lower glass along the circumferential edges of the glasses is filled with a heated glass material to form a one piece sealing with the upper and lower glass. No protection of the glass edges against mechanical impact is provided.

### SUMMARY OF THE INVENTION

It is object of the invention to provide a method of forming a photovoltaic module with edge protection, wherein the edge protection improves moisture protection, edge insulation and protection of the edges against mechanical impact.

The object is solved by a method according to the independent claim. Preferred embodiments are given in the dependent claims.

According to the invention a method for producing a photovoltaic module with edge protection comprises at least the following steps: a) providing a transparent module substrate comprising a thin film solar module on a first surface of the transparent module substrate, b) applying at least two side busbars to the thin film solar module, c) placing a first encapsulation foil onto the thin film solar module, d) placing a transparent back substrate onto the first encapsulation foil, e) placing a second encapsulation foil onto a second surface of the transparent module substrate, f) placing a transparent front substrate onto the second encapsulation foil, g) laminating a substrate stack formed by performing steps a) to f), h) placing a pressure mould over the edge of the substrate stack, i) injecting an edge protection mass into the pressure mould, j) moving the pressure mould along the edges of the substrate stack to form a circumferential edge protection.

Advantageously, by this method a photovoltaic module with edge protection can be manufactured in a time and cost saving way with improved protection of the substrate edges against mechanical damage, penetrating moisture and improved electrical isolation of the module edges. Furthermore, advantageously by this method a frameless photovoltaic module with improved edge protection can be manufactured suitable for building integration photovoltaics. An additional frame for edge protection against mechanical impact and moisture is not necessary because of the formed edge protection.

A thin film solar module consists of a plurality of functional layers known from state of the art, at least comprising a front contact layer, an absorber layer and a back contact layer. The solar module may also comprise intermediate layers, for instance between the front contact layer and the absorber layer or between the absorber layer and the back contact layer. It is obvious that “layer” also comprises layer stacks, for instance front contact, back contact or absorber layer stacks. The thin film solar module is directly arranged on the transparent module substrate, for instance by depositing the functional layers of the thin film solar module onto a first surface of the transparent module substrate.

Often, a first surface of the transparent module substrate means a surface of the transparent module substrate facing away from the sun when the photovoltaic module is in use. In this case, a second surface of the transparent module substrate means a surface of the transparent module substrate facing the sun when the photovoltaic module is in use, meaning the so called sunny side of the thin film solar module. However, this may also be vice versa.

A substrate stack according to the invention means a stack comprising the transparent module substrate with a thin film solar module on a first surface of the transparent module substrate, at least two side busbars applied on the thin film solar module, the transparent back substrate, the transparent front substrate and the first and second encapsulation foils, wherein the first encapsulation foil is arranged on the thin film solar module between the transparent module substrate and the transparent back substrate and the second encapsulation foil is arranged between the transparent module substrate and the transparent front substrate.

In some embodiments, the method further comprises a step of flipping the transparent module substrate with the placed first encapsulation foil and the transparent back substrate on top prior to step e). Flipping means that the transparent module substrate with the first encapsulation foil and the transparent back substrate on top is turned around 180° with respect to an axis extending in a plane parallel to the first surface. The second surface of the transparent module substrate points now upwards.

The encapsulation foils are any known foil suitable for encapsulating a photovoltaic module, for instance the encapsulation foils are selected out of the group of PVB, EVA, POE, TPU, TPT, TPE, PET, BaSO₄-filled PET, PAP, Silicones, Ionomers, UV-curable resins and PU Hybrids as well as others known to experts in the field.

In preferred embodiments before step b) a circumferential isolation cut is performed in step k).

This is advantageously, if the quality of the functional layers deteriorates towards the circumferential edges of the transparent module substrate.

A circumferential isolation cut according to this invention means a cut or groove within which all functional layers of the thin film solar module are removed, wherein the isolation cut follows the edges of the transparent module substrate in a constant distance. That is, no direct or indirect electrical connection exists between the layers or portions arranged at both sides of the groove. The groove thus extends through all functional layers of the thin film solar module till the first surface of the transparent module substrate or even into the transparent module substrate.

The circumferential isolation cut electrically isolates the edges of the transparent module substrate and the functional layers of the thin film solar module and specifies the active area of the thin film solar module. Advantageously, an edge stripping process is no longer required. Further advantageously, the isolation cut can be performed very close to the circumferential edges of the transparent module substrate, so that the active area of the thin film solar module can be maximized. The circumferential isolation cut be performed for instance by a laser process.

In some embodiments, the circumferential isolation cut is performed with a width in the range of 10 μm to 500 μm, preferably 40 μm to 100 μm.

In preferred embodiments in each of the steps a), d) and f) a glass substrate is provided, i.e. as the transparent module substrate, the transparent back substrate and the transparent front substrate.

Advantageously a three-glass photovoltaic module can be manufactured. Furthermore, such a three-glass photovoltaic module has advantages regarding mechanical stability and chemical durability.

A glass substrate may be any glass known from state of the art suitable as transparent module substrate respectively as transparent back or front substrate. The transparent back and front substrate serve thereby as encapsulation material for the thin film solar module arranged on the transparent module substrate. The transparent module substrate serves as substrate material for the thin film solar module.

In some further embodiments, the glass substrates are provided with known thicknesses, for instance in the range of 1 mm to 10 mm.

In other preferred embodiments, the circumferential isolation cut is performed in such a way, that the isolation cut has a distance to the circumferential edges of the transparent module substrate in the range of 200 μm to 10 mm.

Advantageously thereby, the active area of the thin film solar module increases by a given in-plane dimensions of the transparent module substrate, because no state of the art 10 mm to 15 mm wide edge deletion area along the circumferential edges of the transparent module substrate is necessary to achieve a prober isolation of the thin film solar module to the outside and to bond the state of the art butyl strip for sealing directly on the transparent module substrate. Therefor the inventive method is more time and cost efficient as state of the art methods for manufacturing a photovoltaic module with edge protection.

In preferred embodiment in step b) the at least two side busbars are applied such creating each a distance in the range of 0 mm (zero mm) to 10 mm to the circumferential edges of the transparent module substrate.

Side busbars are known and usually applied to a first and a last cell of the thin film solar module, wherein the individual series-connected cells of the thin film solar module are arranged next to one another along a first in-plane direction of the transparent module substrate. A side busbar according to the invention is a conducting line or strip comprising a conducting material to collect and conduct electrical charge carriers generated within the thin film solar module. The distance between a side busbar and the circumferential edges of the transparent module substrate mean a distance between an edge of the side busbar oriented in the direction of the circumferential edges of the transparent module substrate and the circumferential edges of the transparent module substrate.

In some embodiments, the at least two side busbars are applied such that they are arranged along two parallel opposite edges of the transparent module substrate. In some further embodiments, the at least two side busbars are further applied each next to the isolation cut in the direction to the centre of the transparent module substrate. Next to the isolation cut means in very close proximity to the isolation cut, so that each side busbar may be applied directly adjacent to the isolation cut.

In further embodiments, the at least two side busbars are applied in form of a pressure sensitive adhesive tape (known as PSA tape), wherein the PSA tape is applied by unwinding from a roll, placing on the thin film solar module and pressing by a pressure roll. In some embodiments the side busbars have a width of 3.5 mm to 6 mm each, wherein the width of the side busbar is the shorter dimension of the two in plane dimensions of the side busbar, meaning a short edge of a busbar.

Advantageously, because of the increased active area of the thin film solar module through the isolation cut compared to state of the art edge deleted area, the side busbars are longer compared to state of the art, so that more electricity of the thin film solar module can be collected.

In preferred embodiments, in step c) and in step e), the first respectively the second encapsulation foil is placed with in-plane dimensions smaller than the in-plane dimensions of the transparent module substrate creating a distance in the range of 7 mm to 10 mm between the circumferential edges of the transparent module substrate and the encapsulations foils.

Advantageously, this creates an encapsulation foil infeed in the range of 2 mm to 5 mm between the circumferential edges of the substrates and the circumferential edges of the encapsulation foils after laminating in step h). In some embodiments the encapsulation foils extends up to 4 mm in each in-plane direction upon lamination.

In some embodiments, the first and the second encapsulation foils have the same in-plane dimensions. In some further embodiments, the smaller in-plane dimensions of the encapsulation foils create a constant distance in the range of 8 mm to 10 mm between the circumferential edges of the transparent module substrate and the encapsulations foils.

In some further embodiments, the encapsulations foils are placed with known thickness, for instance in the range of 0.3 mm to 1.8 mm.

In some embodiments, the second encapsulation foil is placed congruent to the first encapsulation foil.

In some further embodiments, the first encapsulation foil is placed such that the width of the at least two side busbars are at least partially covered by the first encapsulation foil each.

In preferred embodiments, in step d) and in step f), the transparent back respectively front substrate is placed with in-plane dimensions larger than the in-plane dimensions of the transparent module substrate creating a back respectively front substrate overhang in the range of 2 mm to 5 mm along the circumferential edges of the transparent module substrate.

Advantageously, the created encapsulation foil infeed and the created front respectively back substrate overhang form a filling space filled by the edge protection mass in step j) forming the edge protection. Such formed edge protection offers improved protection against penetrating of moisture into the thin film solar module over the encapsulation foil as well as protection of the substrate edges against mechanical impact and electrical isolation of the thin film module edges to the outside. Further, advantageously a process step of applying a butyl rubber strip along the circumferential edges of the transparent module substrate onto the width of the edge deleted area along the circumferential edges of the substrate is no longer necessary. Furthermore, due to the transparent back respectively front substrate overhang, the transparent module substrate comprising the thin film solar module is protected against mechanical impact.

In some embodiments, the transparent back and the transparent front substrate have the same in-plane dimensions. In some further embodiments, the larger in-plane dimensions of the transparent front and the transparent back substrate create a constant back respectively front substrate overhang in the range of 2 mm to 5 mm along the circumferential edges of the transparent module substrate.

In some embodiments, the transparent front substrate is placed congruent to the transparent back substrate.

In preferred embodiments, before step g), gasses are removed from the substrate stack.

In some embodiments, before removing gasses from the substrate stack, the substrate stack is turned around 180° in a second flipping step. The substrate stack is now placed such that the sunny side of the thin film solar module is pointing downwards.

In other preferred embodiments, removing of gasses is achieved by applying a vacuum to the substrate stack or by squeezing the substrate stack between two rollers.

Especially during squeezing the substrate stack between two rollers, gases can be removed easily because no butyl strip between the transparent module substrate and the transparent back substrate is applied by the inventive method. Thereby advantageously, no bubbles will be formed during lamination in step g) by trapped gasses.

In preferred embodiments, lamination in step g) is performed as a vacuum hot plate lamination or an autoclave lamination process.

Vacuum hot plate lamination and autoclave lamination processes are well-known in state of the art.

Advantageously, no contamination of the hot plate respectively the autoclave occurs, because no butyl strip is applied between the transparent module substrate and the transparent back substrate known from state of the art methods as well as because of the smaller in-plane dimensions of the encapsulations foils.

In preferred embodiments, in step h) the pressure mould placed over the edges of the substrate stack is formed such that it creates a filling space with a curved outer shape extending from an upper to a lower surface of the substrate stack.

Advantageously the filling space is filled with the edge protection mass in step j) to form the edge protection.

For this, the pressure mould needs to have an inner shape corresponding to the outer shape of the filling space.

The filling space created by placing the pressure mould over the edges of the substrate stack has a curved outer shape extending from an upper to a lower surface of the substrate stack and an inner shape defined by the edge contours of the transparent module substrate, the transparent back respectively front substrate and the created transparent back respectively front substrate overhang and encapsulation foil infeed.

A curved outer shape means a shape created by a curved line through connecting the edge of the upper surface of the substrate stack with the edge of the lower surface of the substrate stack. In some embodiments, the curved line is an arc of a circle having its centre at a position inside the substrate stack or even outside the opposite edge of the substrate stack. The radius of the circle may lie in the range of 7 mm to 30 mm.

A curved line may also mean a line whose curvature changes at least once along the length of the line. Advantageously a variety of curved outer shapes of the edge protection are possible. For instance, the curved line may be a segment of an ellipse. In some embodiments, the curved line may consist of a number of line segments, wherein these line segments may be straight line segments connected together to form a curved line. Other embodiments of the curved line may comprise at least two convex segments and one concave segment connecting the convex segments, wherein the convex segments are arranged adjacent to the upper or the lower surface of the substrate stack, respectively. In other embodiments, the curved line may comprise a plurality of different convex segments, wherein at least two segments have a different radius. “Convex” means in each case that the middle of the segment has a larger distance to the edge of the substrate stack as the endpoints of the respective segment.

Furthermore, advantageously in an arrangement of different photovoltaic modules with an edge protection comprising such a curved outer shape each, adjacent photovoltaic modules comprise curved outer shapes of the edge protection corresponding to each other. Corresponding to each other means that a curved outer shape created of the edge protection of a first photovoltaic module corresponds to a curved outer shape of at least one second photovoltaic module. This means that the curvature of the curved lines run opposite to each other. Advantageously, a kind of tongue-and-groove connection is formed such. Furthermore, the outer shapes of the edge protection of two adjacent photovoltaic modules may be formed such that, when the respective photovoltaic modules are brought together, channels or cavities for water drain (drip moulding) or for electrical wires or other devices remain, thereby providing additional functionality arising from the particular interconnection of the curved outer shapes.

In some embodiments, the curved line connects the edge of the upper surface of the substrate stack with the edge of the lower surface of the substrate stack such that the filling space respectively edge protection has an extension in a direction from inside the substrate stack to the outside of at least 1 mm starting from any point of the edge contours of the transparent front respectively back substrate. Advantageously, this forms a bumping zone of the edge protection.

The upper respectively lower surface of the substrate stack mean surfaces of the substrate stack opposite to each other and facing the outside when the photovoltaic module is in use, wherein one surface faces the sun and the opposite surface faces an installation area of the photovoltaic module. The upper surface of the substrate stack may be the surface of the transparent back substrate facing to the outside and the lower surface of the substrate stack may be the surface of the transparent front substrate facing to the outside.

An outer shape of the filling space corresponds to an outer shape of the edge protection and means a shape of the filling space respectively edge protection directed to the outside.

An inner shape of the filling space corresponds to an inner shape of the edge protection and means a shape of the filling space respectively edge protection directed to the centre of the photovoltaic module.

In some embodiments, the cross section of the filling space respectively edge protection comprises a curved outer shape and a specific inner shape. The specific inner shape is formed by a line starting at the edge of the upper surface of the substrate stack following an edge contour of the transparent back substrate and further on the transparent back substrate overhang and the encapsulation infeed of the first encapsulation foil along a surface of the transparent back substrate. The line follows further the thickness of the first encapsulation foil and the encapsulation foil infeed of the first encapsulation foil along the first surface of the transparent module substrate and further following the edge contour of the transparent module substrate and the encapsulation foil infeed of the second encapsulation foil along the second surface of the transparent module substrate. The line follows further the thickness of the second encapsulation foil and the encapsulation foil infeed of the second encapsulation foil along a surface of the transparent front substrate and an edge contour of the transparent front substrate ending at the edge of the lower surface of the substrate stack.

An edge contour means the specific shape of the circumferential edges of the transparent module substrate and the transparent back and front substrate. The edge contour may any of the known contours, for instance a rounded edge contour, a straight contour or a chamfered contour.

Part of the invention is also a pressure mould suitable for placing over the substrate stack, wherein the pressure mould comprises an inner shape for creating a filling space. The inner shape of the pressure mould comprises a curved inner shape created by a curved line whose curvature may change at least once along the length of the curved line.

In preferred embodiments, in step i) a heated edge protection mass is injected into the pressure mould, where the heated edge protection mass is selected out of the group butyl masses, polyolefins, silicon rubbers, polycarbonate, polyamides, polybutene copolymers, polyurethane, ethylene-acrylate-copolymers, ethylene-acrylate-maleic-anhydride terpolymers, ethylene-vinylacetate-maleic-anhydride terpolymers.

Advantageously, the edge protection mass offers edge protection against mechanical impact, electrical isolation of the thin film solar module edge against the outside and prevents moisture penetration to the thin film solar module, when it is cooled down and solidified.

In some embodiments the edge protection mass is heated up to temperatures in the range of 150° C. to 230° C.

Known ethylene-acrylate-copolymers are for example ethylene-ethyl acrylate (EEA), ethylene-butyl acrylate (EBA), ethylene n-butyl acrylate (EnBA), ethylene acrylic acid (EAA).

Known polyolefins are for example low density polyethylene (LDPE) and high density polyethylene (HDPE).

In further embodiments the edge protection mass may be any known hot-melt or heat-setting polymer known by experts in the field, which is suitable to ensure sufficient moisture barrier qualities with electrical insulation and deformability properties to create an edge protection.

In further embodiments the edge protection mass comprises a flame class rating according to UL 94 of HB and/or a water vapor transmission rate WVTR at 38° C., 100% RH for 1, 52 mm film according to ASTM F1249 of at least 0.3 g/square meter per day and/or a Volume Resistivity according to IEC 62788-1-2 of 10¹⁴ Ohm·cm and/or retains >70% of initial adhesive and electrical properties after 1000 hours UV exposure according to UL 746C ASTM G155 Cycle 1 and/or Thermal Endurance (RTI, RTE) per UL 746B 105° C. retains >50% of initial properties after required heat exposure.

The edge protection is formed by simultaneously performing step i) and j).

The invention further concerns the use of the inventive method for producing a photovoltaic module with edge protection.

In some embodiments, the inventive method is used to manufacture a frameless three-glass photovoltaic module for building integration.

The invention further concerns a photovoltaic module comprising at least a transparent module substrate comprising a thin film solar module on a first surface of the transparent module substrate; a transparent back substrate arranged on the thin film solar module; a transparent front substrate arranged on a second surface of the transparent module substrate; at least two side busbars and a circumferential edge protection. The transparent module substrate, the transparent back substrate and the transparent front substrate form a substrate stack, and the at least two side busbars are arranged on the thin film solar module. Further, the transparent back substrate is laminated to the thin film solar module and the transparent front substrate is laminated to the second surface of the transparent module substrate each via encapsulation foils. Furthermore, the first respectively the second encapsulation foil have in-plane dimensions smaller than the in-plane dimensions of the transparent module substrate creating an encapsulation foil infeed in the range of 2 mm to 5 mm between the circumferential edges of the transparent module substrate and circumferential edges of the encapsulation foils in the laminated substrate stack. The transparent back respectively front substrate have in-plane dimensions larger than the in-plane dimensions of the transparent module substrate creating a back respectively front substrate overhang in the range of 2 mm to 5 mm along the circumferential edges of the transparent module substrate. Further, the circumferential edge protection is made of an edge protection mass selected out of the group butyl masses, polyolefins, silicon rubbers, polycarbonate, polyamides, polybutene copolymers, polyurethane, ethylene-acrylate-copolymers, ethylene-acrylate-maleic-anhydride terpolymers, ethylene-vinyl, acetate-maleic-anhydride terpolymers and comprises a curved outer shape extending from an upper to a lower surface of the substrate stack.

Advantageously, such a frameless photovoltaic module comprises an edge protection with improved protection against mechanical impact and penetration of moisture and an improved electrical isolation.

In some embodiments, the edge protection comprises three zones, a moisture zone preventing penetrating moisture into the thin film solar module, an isolation zone providing electrical isolation of the thin film solar module edge to the outside, and a bumping zone protecting the thin film solar module edge against mechanical impact. The moisture zone extends thereby completely along a cross-sectional thickness of the edge protection, i.e. from the outer edge of the edge protection to the edge of the encapsulation foils. The isolation zone extends along the cross-sectional thickness of the edge protection from the edge of the transparent module substrate to the edges of the transparent front and back substrate and corresponds to the transparent back respectively front substrate overhang. The bumping zone extends along the cross-sectional thickness of the edge protection and is delimited by the transparent back respectively front substrate edge and the outer shape of the edge protection. Advantageously, in case the bumping zone is compressed and may therefore not contribute to electrical insulation any more, electrical insulation is still given by the isolation zone.

The cross-sectional thickness of the edge protection means the longest extension of the edge protection along a direction from the centre of the photovoltaic module to the outside and delimited by the encapsulation foil infeed and the outer shape of the edge protection.

In some embodiments, the circumferential edge protection comprises a constant outer shape along the entire length of the circumferential edge protection. In further embodiments, the circumferential edge protection comprises different outer shapes along the length of the circumferential edge protection. In some further embodiments, the circumferential edge protection comprises several recesses within the outer shape of the circumferential edge protection wherein these recesses may be oriented along a direction perpendicular to the in-plane directions of the transparent module substrate. Advantageously, these recesses can serve as water channels or water channels may be arranged within these recesses ensuring drainage of water when the photovoltaic modules are installed and in use. Furthermore, these recesses may be used for admission of electrical cables or other devices during installation and use of the photovoltaic module.

In preferred embodiments, the transparent module substrate, respectively back and front substrate are glass substrates.

Advantageously the photovoltaic module is a three-glass photovoltaic module. Furthermore, advantageously the photovoltaic module is a frameless photovoltaic module suitable for building integration.

In some embodiments, the inventive photovoltaic module is used for building integration photovoltaic modules.

In preferred embodiments, the circumferential edge protection comprises a DC dielectric strength of at least 10 kV/mm according to IEC 60243-1.

For realization of the invention it is advantageous to combine the described embodiments and features of the claims as described above. However, the embodiments of the invention described in the foregoing description are examples given by way of illustration and the invention is nowise limited thereto. Any modification, variation and equivalent arrangement as well as combinations of embodiments should be considered as being included within the scope of the invention.

### DESCRIPTION OF DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 shows a process scheme of an embodiment of the inventive method for manufacturing a photovoltaic module with edge protection.

FIGS. 2A to 2F show exemplary embodiments of the inventive method by means of cross-sectional and plane views on a photovoltaic module at different process steps.

FIG. 3A shows a portion of an exemplary embodiment of a photovoltaic module comprising an edge protection and manufactured according to the inventive method.

FIG. 3B shows the edge protection of FIG. 3A alone.

### REFERENCE SIGNS

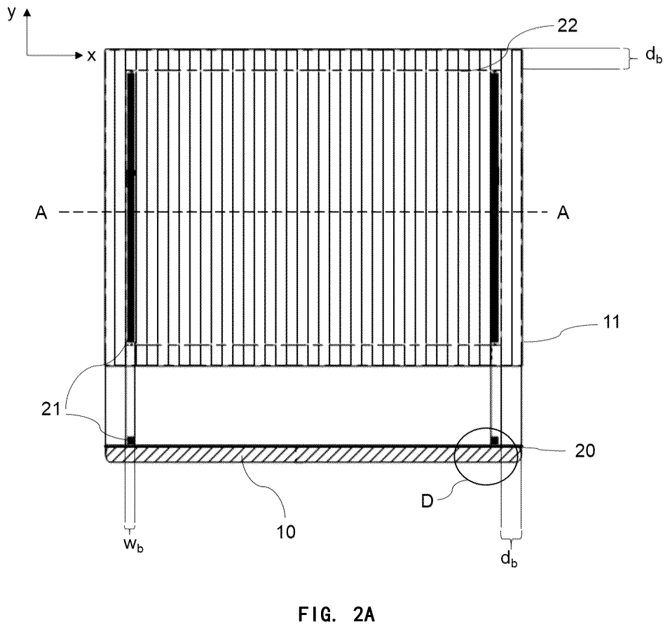

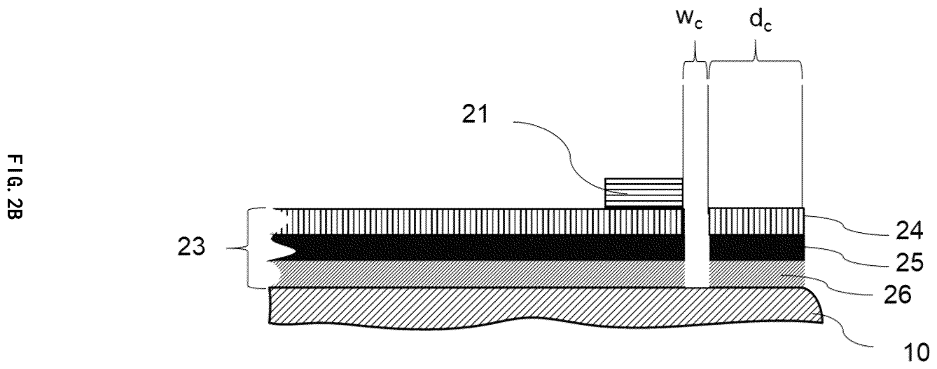

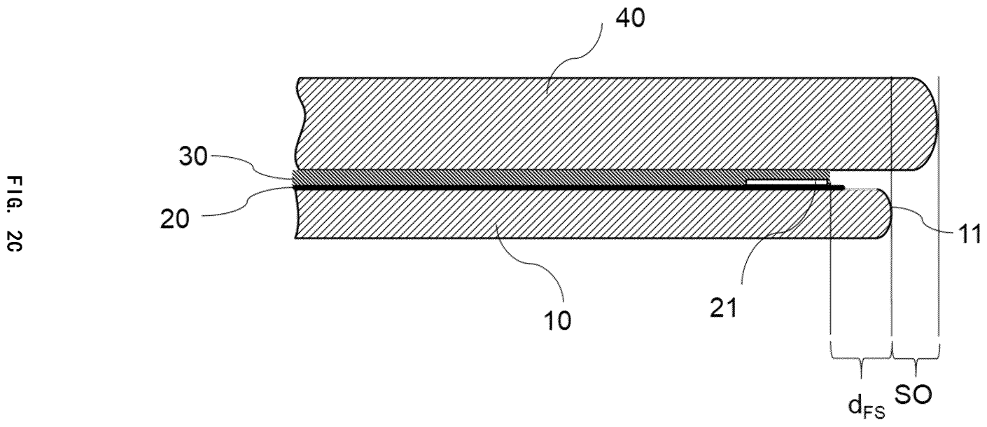

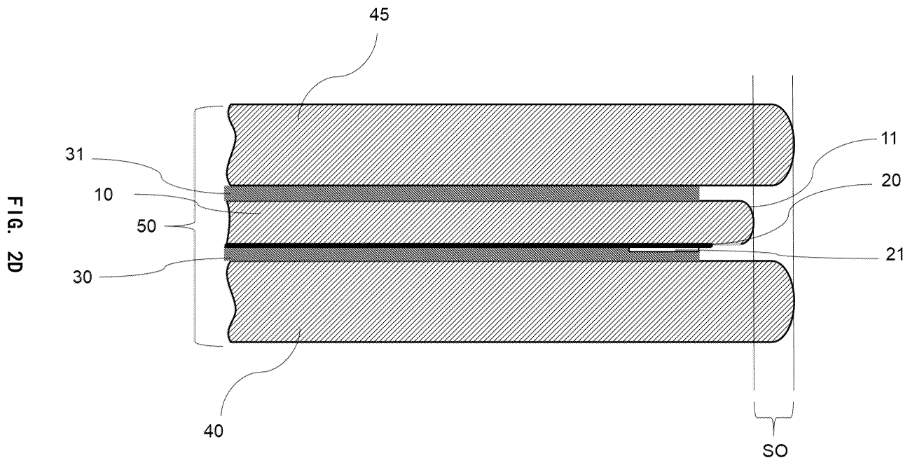

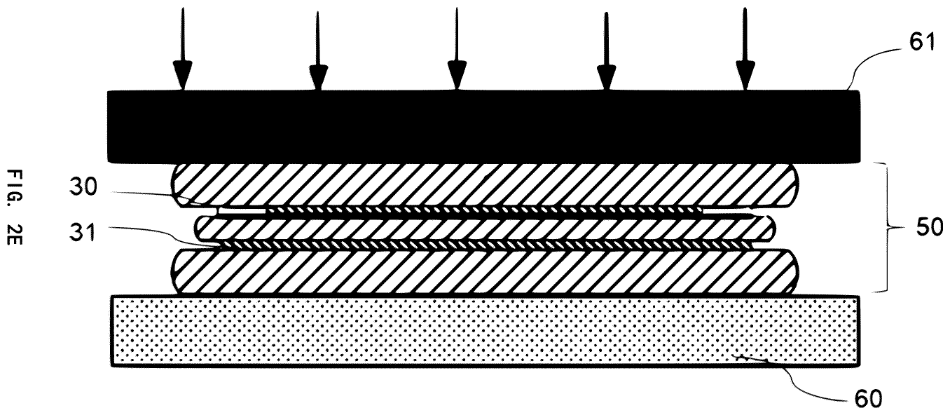

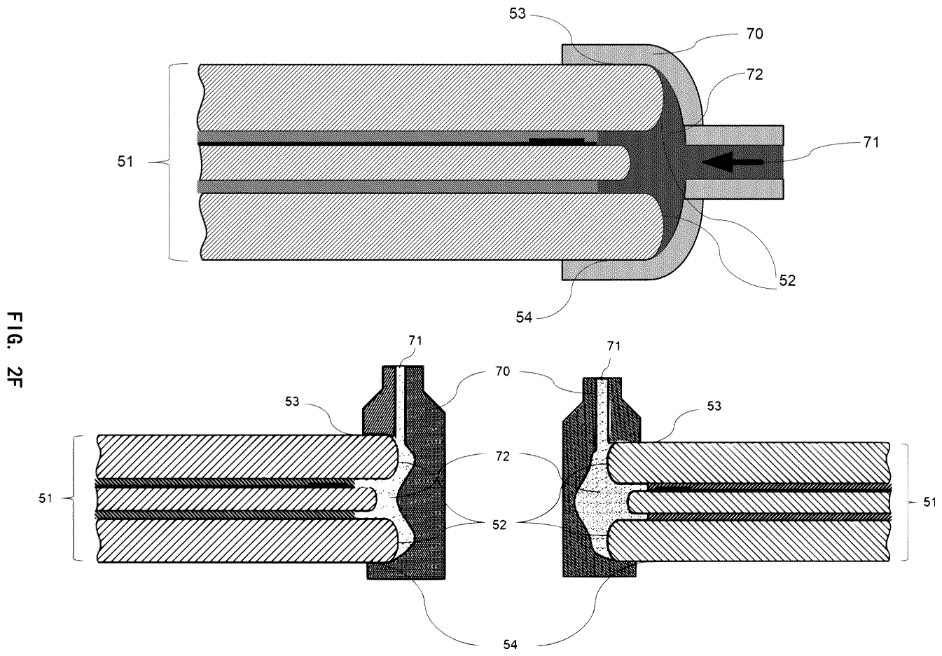

10 Transparent module substrate
11 Edge of the transparent module substrate
12 First surface of the transparent module substrate
13 Second surface of the transparent module substrate
20 Thin film solar module
21 Side busbar
22 Circumferential isolation cut
23 Layer stack
24 Back contact electrode
25 Absorber layer
26 Front contact electrode
30 First encapsulation foil
31 Second encapsulation foil
40 Transparent back substrate
41 Edge of the transparent back substrate
45 Transparent front substrate
50 Substrate stack
51 Laminated substrate stack
52 Edge of the laminated substrate stack
53 Upper surface of the laminated substrate stack
54 Lower surface of the laminated substrate stack
60 Heating plate
61 Pressure plate
70 Pressure mould
71 Heated edge protection mass
72 Filling space
80 Edge protection
100 Photovoltaic module
D Detail of FIG. 2A
d_{b} Distance of the side busbar from the edge of the transparent module substrate
d_{c} Distance of the isolation cut from the edge of the transparent module substrate
d_{FF} Encapsulation foil infeed
d_{FS} Distance of the edge of the first encapsulation foil from the edge of the transparent module substrate before lamination
SO Substrate overhang
w_{b} Width of the side busbar
w_{c} Width of the circumferential isolation cut DETAILED DESCRIPTION

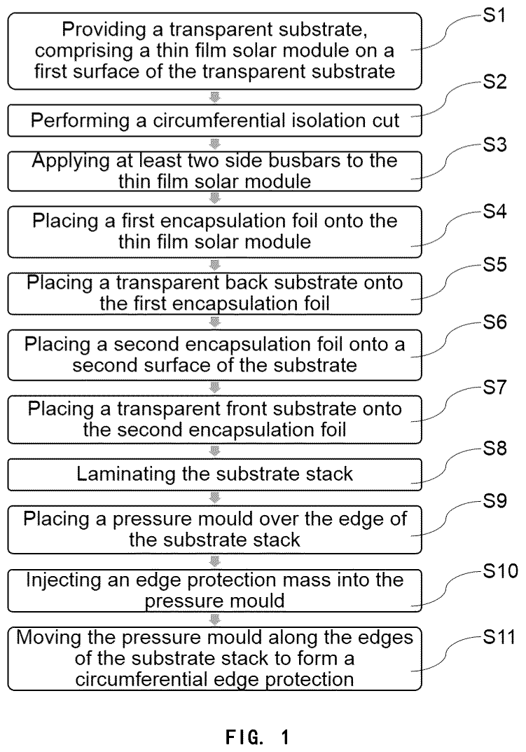

FIG. 1 shows a process scheme of an embodiment of a method for manufacturing a photovoltaic module with edge protection. In step S1, a transparent module substrate comprising a thin film solar module on a first surface of the transparent module substrate is provided (step a)). Next, in S2, a circumferential isolation cut is performed (step k)) for defining the active area of the thin film module. In other embodiments, step S2 is not performed, if the quality of the functional layers of the thin film solar module is not deteriorating towards the edges of the transparent module substrate. In S3, at least two side busbars are applied to the thin film solar module (step b)), followed by S4 of placing a first encapsulation foil onto the thin film solar module (step c)). Next, in S5, a transparent back substrate is placed onto the first encapsulation foil (step d)). In a next step S6, a second encapsulation foil is placed onto a second surface of the transparent module substrate (step e)), followed by S7 of placing a transparent front substrate onto the second encapsulation foil (step f)). In S8, a substrate stack formed by steps S1 to S7 is laminated (step g)), followed by placing a pressure mould over the edge of the substrate stack in S9 (step h)). Next in S10, a heated edge protection mass is injected into the pressure mould (step i)) and then, in S11, the pressure mould is moved along the edges of the substrate to form a circumferential edge protection (step j)).

Steps S1 to S7 may be advantageously performed in the order or sequence shown in FIG. 1. However, some of these steps may also be performed in other orders, wherein, nevertheless, some steps have to follow some other steps. For instance, step S2 to S7 must be performed after step S1, step S4 must be performed after step S3, step S5 must be performed after step S4 and step S7 must be performed after step S6. Furthermore, step S2 has to be performed before step S5 and is advantageously performed before step S3. In other words: The isolation cut (step S2 or k)) may be performed even after applying the side busbars and the first encapsulation foil, but is performed before applying the transparent back substrate, and the second encapsulation foil and the transparent front substrate may be applied before performing steps S2 to S5.

FIG. 2A shows a plane view of a photovoltaic module after step S3 in the upper part and the corresponding cross-sectional view of the photovoltaic module along the line AA in the lower part. The photovoltaic module at this process stage comprises a transparent module substrate 10, a thin film solar module 20 and at least two side busbars 21. Furthermore, a circumferential isolation cut 22 is formed and can be seen in the plane view. The thin film solar module 20 is formed of a plurality of thin film solar cells arranged next to one another along a first in-plane direction of the transparent module substrate, i.e. x-direction in FIG. 2A, and electrically connected with each other, for instance in series. The side busbars 21 having a width w_{b} of 5 mm are applied to a first and a last cell of the thin film solar module 20. Each of the side busbars 21 has a distance d_{b} of 4 mm to the circumferential edges 11 of the transparent module substrate 10. Here a short as well as a long edge of one side busbar 21 has a distance to the circumferential edges 11 of the transparent module substrate 10, wherein the long edge of the side busbar 21 is that edge of the side busbar 21 extending vertical to the first in-plane direction (x-direction) of the transparent module substrate 10 und the short edge is an edge of the side busbar 21 directed along the first in-plane direction of the transparent module substrate 10.

FIG. 2B shows detail D of FIG. 2A, i.e. an edge region of the photovoltaic module in the cross-sectional view. The thin film solar module 20 is formed of a layer stack 23 comprising a back contact layer 24, an absorber layer 25 and a front contact layer 26. The front contact layer 26 is made of a transparent conductive material, for instance a transparent conductive oxide. The absorber layer 25 may be, for instance, CdTe or CdSeTe having a suitable composition. The back contact layer 24 may be formed of a metal or a transparent conductive material or any other suitable conductive material. As understood by a person skilled in the art, each layer of the layer stack 23 may be a layer stack comprising different layers. Different isolation cuts and interconnections forming and connecting individual thin film solar cells within the layer stack are provided, but not shown in FIG. 2B for sake of lucidity. The layer stack 23 is formed on the transparent module substrate 10 almost to its edge 11. The circumferential isolation cut having a width w_{c} of 40 μm is formed with a distance d_{c} of 4 mm from the edge 11 of the transparent module substrate 10 such that it extends through the whole layer stack 23. The side busbar 21 shown in FIG. 2B is arranged on the layer stack 23 such that is in contact with the back contact layer 24 on that side of the circumferential isolation cut 22 which is away from the edge 11 of the transparent module substrate 10.

FIG. 2C shows a cross-sectional view of a portion of the photovoltaic module after step S5. Visible is the transparent module substrate 10 comprising the thin film solar module 20 with one side busbar 21. Onto the thin film solar module 20, a first encapsulation foil 30 is placed, and on top of the first encapsulation foil 30, a transparent back substrate 40 is placed. The first encapsulation foil 30 has in-plane dimensions, i.e. dimensions in the x-y-plane, smaller than the in-plane dimensions of the transparent module substrate 10 creating a distance d_{FS} in the range of 8 mm to 10 mm between the circumferential edge 11 of the transparent module substrate 10 and the encapsulation foil 30. The transparent back substrate 40 has in-plane dimensions larger than the in-plane dimensions of the transparent module substrate 10 creating a back substrate overhang SO, i.e. the distance of the edge 11 of the transparent module substrate 10 to an edge 41 of the transparent back substrate 40, in the range of 2 mm to 5 mm along the circumferential edge 11 of the transparent module substrate 10.

FIG. 2D shows a cross-sectional view of the photovoltaic module after step S7. Visible is a substrate stack 50 comprising the transparent module substrate 10 with the thin film solar module 20, the transparent back substrate 40, a transparent front substrate 45, the first encapsulation foil 30 and a second encapsulation foil 31 arranged between the transparent module substrate 10 and the transparent back substrate 40 respectively between the transparent module substrate 10 and the transparent front substrate 45. As can be seen, the transparent front and back substrate 40, 45 each have larger in-plane dimensions than the transparent module substrate 10 creating a transparent back respectively front substrate overhang SO in the range of 2 mm to 5 mm each along the circumferential edge 11 of the transparent module substrate 10.

FIG. 2E shows a cross-sectional view of the photovoltaic module during step S8. In this embodiment, a vacuum hot plate process is carried out to form a laminated substrate stack 51 by melting the first and second encapsulation foils 30, 31. The substrate stack 50 is placed on a heating plate 60 with a temperature of approximately 150° C. and a pressure plate 61 is placed on top of the substrate stack 50 to apply a pressure of approximately 50 kPa to the substrate stack 50 during laminating in step S8.

FIG. 2F shows different embodiments of a cross-sectional view of the photovoltaic module during step S10. In each case a pressure mould 70 is placed over an edge 52 of the laminated substrate stack 51 and a heated edge protection mass 71 in injected in the pressure mould 70. A filling space 72 with a curved outer shape extending from an upper surface 53 to a lower surface 54 of the laminated substrate stack 51 is created by placing the pressure mould 70 over the edge 52 of the laminated substrate stack 51, wherein an inner shape of the pressure mould 70 corresponds to the outer shape of the filling space 72. The different embodiments in FIG. 2F show different fillings spaces 72 with different curved outer shapes resulting in edge protection with different curved outer shapes. In these embodiments, an edge protection mass 71 of Polyisobutylene Butyl rubber adhesive with integrated desiccant is heated to 190° C. and injected in the pressure mould 70 to form an edge protection after cooling and consolidation in each case. By moving the pressure mould 70 along the whole circumference of the laminated substrate stack 51, a closed circumferential edge protection of the photovoltaic module is formed. The right part of FIG. 2F shows an exemplary embodiment of different laminated substrate stacks 51 with placed pressure moulds 70, wherein the pressure moulds 70 create filling spaces 72 with corresponding curved outer shapes to form edge protections corresponding to each other as a kind of tongue-and-groove connection.

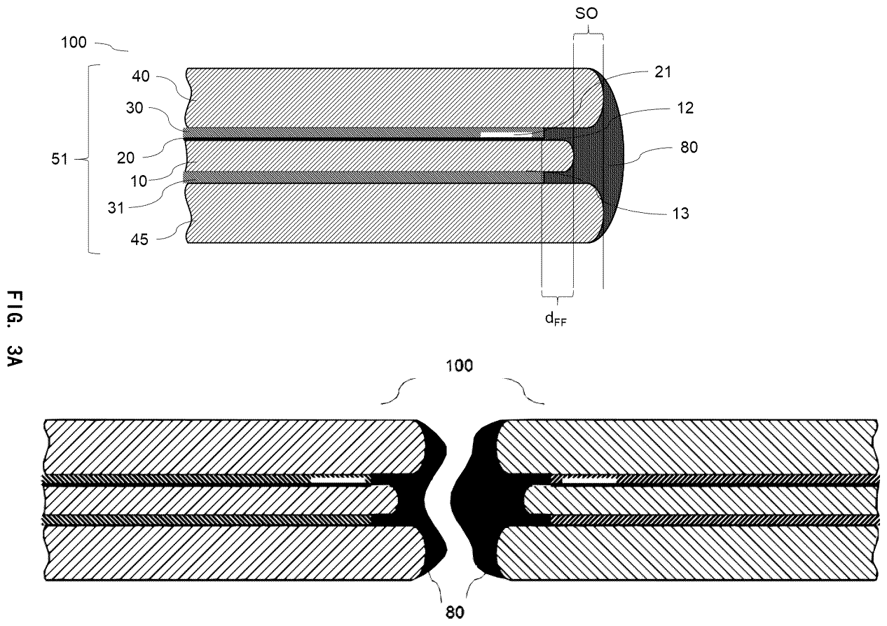

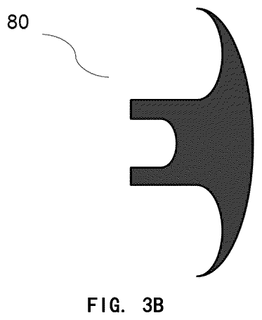

FIG. 3A shows different embodiments of a cross-sectional view of a portion of a photovoltaic module 100 manufactured according to an inventive method and comprising an edge protection 80 in each case, and FIG. 3B shows the edge protection 80 of left part of FIG. 3A alone. Thus, the curved outer shape and the specific inner shape of the edge protection 80 can be better seen. The right part of FIG. 3A shows photovoltaic modules 100 with edge protections with different curved outer shapes forming a kind of tongue-and-groove connection.

The photovoltaic module 100 comprises a transparent module substrate 10 with a thin film solar module 20 on a first surface 12 of the transparent module substrate 10, a transparent back substrate 40 arranged on the thin film solar module 20, a transparent front substrate 45 arranged on a second surface 13 of the transparent module substrate 10, at least two side busbars 21, and a circumferential edge protection 80. The at least two side busbars 21 are arranged on the thin film solar module 20. The transparent back substrate 40 is laminated to the thin film solar module 20 and the transparent front substrate 45 is laminated to the second surface 13 of the transparent module substrate 10 each via encapsulation foils 30, 31. The transparent module substrate 10, the transparent back substrate 40 and the transparent front substrate 45 form a laminated substrate stack 51 together with the encapsulation foils 30, 31 and the thin film solar module 20 and the side busbars 21. The first respectively the second encapsulation foil 30, 31 have in-plane dimensions smaller than the in-plane dimensions of the module substrate 10 creating an encapsulation foil infeed d_{FF} in the range of 2 mm to 5 mm. The encapsulation foil infeed d_{FF} is the distance between the circumferential edge 11 of the module substrate 10 and an circumferential edge of the respective encapsulation foil 30, 31 in the laminated substrate stack 51. The transparent back respectively front substrate 40, 45 have in-plane dimensions larger than the in-plane dimensions of the module substrate 10 creating a back respectively front substrate overhang SO in the range of 2 mm to 5 mm along the circumferential edges of the laminated substrate stack 51. The circumferential edge protection 80 is made of an edge protection mass selected out of the group butyl masses, polyolefins, silicon rubbers, polycarbonate, polyamides, polybutene copolymers, polyurethane, ethylene-acrylate-copolymers, ethylene-acrylate-maleic-anhydride terpolymers, and ethylene-vinylacetate-maleic-anhydride terpolymers, and comprises a curved outer shape extending from an upper surface 53 to a lower surface 54 of the laminated substrate stack 51.

According to FIG. 3A, the specific inner shape of the edge protection 80, i.e. that portion of the edge protection 80 being in contact with the laminated substrate stack 51, is formed by a line starting at the edge of the upper surface 53 of the laminated substrate stack 51 following an edge contour of the transparent back substrate 40 and further extending along a surface of the transparent back substrate 40, the surface facing away from the upper surface 53 of the laminated substrate stack 51, over the transparent back substrate overhang SO and the encapsulation infeed d_{FF} of the first encapsulation foil 30. The line follows further a thickness of the first encapsulation foil 30 and extends along the first surface 12 of the transparent module substrate 10 over the encapsulation foil infeed d_{FF} of the first encapsulation foil 30, and further follows the edge contour of the transparent module substrate 10 and extends along the second surface 13 of the transparent module substrate 10 over the encapsulation foil infeed d_{FF} of the second encapsulation foil 31. The line follows further a thickness of the second encapsulation foil 31 and extends along a surface of the transparent front substrate 45, the surface facing away from the lower surface 54 of the laminated substrate stack 51, over the encapsulation foil infeed d_{FF} of the second encapsulation foil 31 and an edge contour of the transparent front substrate 45 ending at the edge of the lower surface 54 of the laminated substrate stack 51.

The outer shape of the edge protection 80 is given by a curved line through connecting the edge of the upper surface 53 of the laminated substrate stack 51 with the edge of the lower surface 54 of the laminated substrate stack 51. In an embodiment according to FIG. 3B, the curved line is an arc of a circle having its centre at a position inside the laminated substrate stack 51 or even outside the opposite edge of the laminated substrate stack 51. The radius of the circle may lie in the range of 7 mm to 30 mm.

Thus, the edge protection 80 has a convex outer shape and an inner shape comprising a recess for the transparent module substrate 10 and at least partial recesses for the transparent back and front substrate 40, 45 and two protrusions filling in the space created by the encapsulation foil infeeds d_{FF}. The edge protection 80 further fills in the space created by the overhangs SO and covers, and thereby protects, the edges of the transparent back and front substrates 40, 45 as well as the edge 11 of the transparent module substrate 10.

1. Method for producing a photovoltaic module with edge protection comprising at least the following steps:
a) providing a transparent module substrate comprising a thin film solar module on a first surface of the transparent module substrate,
b) applying at least two side busbars to the thin film solar module,
c) placing a first encapsulation foil onto the thin film solar module,
d) placing a transparent back substrate onto the first encapsulation foil,
e) placing a second encapsulation foil onto a second surface of the transparent module substrate,
f) placing a transparent front substrate onto the second encapsulation foil,
g) laminating a substrate stack formed by performing steps a) to f),
h) placing a pressure mould over the edge of the substrate stack,
i) injecting an edge protection mass into the pressure mould,
j) moving the pressure mould along the edges of the substrate stack to form a circumferential edge protection.

2. Method according to claim 1, characterized in that, before step b), a circumferential isolation cut is performed in step k).

3. Method according to claim 1 or 2, characterized in that a glass substrate is provided for each of the transparent module substrate, the transparent back substrate and the transparent front substrate.

4. Method according to one of the claims 1 to 3, characterized in that the circumferential isolation cut is performed in such a way that the isolation cut has a distance to the circumferential edges of the transparent module substrate in the range of 0.2 mm to 10 mm.

5. Method according to one of the claims 1 to 4, characterized in that, in step b), the at least two side busbars are applied such having each a distance in the range of 0 mm to 10 mm to the circumferential edges of the transparent module substrate.

6. Method according to one of the claims 1 to 5, characterized in that, in step c) and in step e), the first respectively the second encapsulation foil is placed with in-plane dimensions smaller than the in-plane dimensions of the transparent module substrate creating a distance in the range of 7 mm to 10 mm between the circumferential edges of the transparent module substrate and the encapsulations foils.

7. Method according to one of the claims 1 to 6, characterized in that, in step d) and in step f), the transparent back respectively front substrate is placed with in-plane dimensions larger than the in-plane dimensions of the transparent module substrate creating a back respectively front substrate overhang in the range of 2 mm to 5 mm along the circumferential edges of the transparent module substrate.

8. Method according to one of the claims 1 to 7, characterized in that, before step g), gasses are removed from the substrate stack.

9. Method according to claim 8, characterized in that removing of gasses is achieved by applying a vacuum to the substrate stack or by squeezing the substrate stack between two rollers.

10. Method according to one of the claims 1 to 9, characterized in that lamination in step g) is performed as a vacuum hot plate lamination or an autoclave lamination process.

11. Method according to one of the claims 1 to 10, characterized in that, in step h), the pressure mould placed over the edges of the substrate stack is formed such that it creates a filling space with a curved outer shape extending from an upper surface to a lower surface of the substrate stack.

12. Method according to one of the claims 1 to 11, characterized in that, in step i), a heated edge protection mass is injected into the pressure mould, where the heated edge protection mass is selected out of the group butyl masses, polyolefins, silicon rubbers, polycarbonate, polyamides, polybutene copolymers, polyurethane, ethylene-acrylate-copolymers, ethylene-acrylate-maleic-anhydride terpolymers, ethylene-vinylacetate-maleic-anhydride terpolymers.

13. Use of the method according to any of the claims 1 to 12 for producing a photovoltaic module with edge protection.

14. Photovoltaic module comprising at least:
a transparent module substrate comprising a thin film solar module on a first surface of the transparent module substrate,
a transparent back substrate arranged on the thin film solar module,
a transparent front substrate arranged on a second surface of the transparent module substrate,
at least two side busbars,
a circumferential edge protection,
wherein
the transparent module substrate, the transparent back substrate and the transparent front substrate form a substrate stack,
the at least two side busbars are arranged on the thin film solar module,
the transparent back substrate is laminated to the thin film solar module and the transparent front substrate is laminated to the second surface of the transparent module substrate each via encapsulation foils,
the first respectively the second encapsulation foil have in-plane dimensions smaller than the in-plane dimensions of the transparent module substrate creating an encapsulation foil infeed in the range of 2 mm to 5 mm between the circumferential edges of the transparent module substrate and circumferential edges of the encapsulations foils after laminating the substrate stack,
the transparent back respectively front substrate have in-plane dimensions larger than the in-plane dimensions of the transparent module substrate creating a back respectively front substrate overhang in the range of 2 mm to 5 mm along the circumferential edges of the substrate,
the circumferential edge protection is made of an edge protection mass selected out of the group butyl masses, polyolefins, silicon rubbers, polycarbonate, polyamides, polybutene copolymers, polyurethane, ethylene-acrylate-copolymers, ethylene-acrylate-maleic-anhydride terpolymers, ethylene-vinylacetate-maleic-anhydride terpolymers, and
the edge protection comprises a curved outer shape extending from an upper to a lower surface of the substrate stack.

15. Photovoltaic module according to claim 14, characterized in that the transparent module substrate, respectively back and front substrate are glass substrates.

16. Photovoltaic module according to claim 14 or 15, characterized in that the circumferential edge protection comprises a DC dielectric strength of at least 10 kV/mm according to IEC 60243-1.
